(19) United States
(12) Patent Application Publication
(10) Pub. No.: US 2009/0211632 A1
(43) Pub. Date: Aug. 27, 2009

(54) PHOTOVOLTAIC DEVICE BASED ON CONFORMAL COATING OF COLUMNAR STRUCTURES

(75) Inventors: Michael Julian Brett, Edmonton (CA); Jillian M. Buriak, Edmonton (CA); Michael D. Fleischauer, Edmonton (CA); Nathan J. Gerein, Edmonton (CA); Kenneth D. Harris, Edmonton (CA); Sean A. McClure, Edmonton (CA); David A. Rider, Edmonton (CA)

Correspondence Address: CHRISTENSEN, O'CONNOR, JOHNSON, KINDNESS, PLLC, 1420 FIFTH AVENUE, SUITE 2800, SEATTLE, WA, 98101-2347, US

(73) Assignees: THE GOVERNORS OF THE UNIVERSITY OF ALBERTA, Edmonton (CA); NATIONAL RESEARCH COUNCIL OF CANADA, Ottawa (CA)

(21) Appl. No.: 12/370,429

(22) Filed: Feb. 12, 2009

Related U.S. Application Data
(60) Provisional application No. 61/028,111, filed on Feb. 12, 2008.

(51) Int. Cl. H01L 31/0352; H01L 31/18

(52) U.S. Cl. 136/256; 438/57; 257/E31.038

(57) ABSTRACT

A photovoltaic device, comprises a first electrode, an electron donor layer in electrical contact with the first electrode, an electron acceptor layer in contact with the electron donor layer across an interface having a shape defined by a columnar structure grown by oblique angle deposition, and a second electrode in electrical contact with the electron acceptor layer.

### TECHNICAL FIELD

Columnar photovoltaic devices

### BACKGROUND

A photovoltaic device, or solar cell, harvests incoming electromagnetic radiation and converts this energy into electricity. In an excitonic solar cell, sunlight is absorbed within the device, and energetic particles known as excitons are generated. These excitons consist of strongly interacting pairs of electrons and holes, which are treated as single bound particles. In order to extract electrical energy from excitons, the excitons must first migrate to an interface that is capable of separating their component charges. Then the electrons and holes must be separated, and transported to electrodes where they are removed from the photovoltaic device to make up an electrical current.

To maximize the performance of a photovoltaic cell, a number of constraints must be placed over the materials and geometry. First, sunlight must be absorbed within the cell, and therefore one or more materials within the cell must be capable of efficiently absorbing sunlight in the range of about 250 nm-2000 nm, to form excitons. Second, these excitons must be broken down into separate electrons and holes. This process generally requires an interface between electron donating and electron accepting materials, and therefore, a photovoltaic device must incorporate both types of materials, either or both of which may absorb incident light. Moreover, to ensure efficient conversion of light into electricity, the areal density of donor/acceptor interface must be as large as possible, with domain widths on the order of the exciton's diffusion length, to minimize excitonic decay, e.g. electron-hole recombination. Third, once separated, charged particles must be transported from the donor and acceptor materials to the charge collection electrodes so that current will flow. This requires a continuous electrical conduction path for both electrons and holes, emanating from any point where excitons are separated into electrons and holes. At no point along the conduction path can large energy barriers be present including all material interfaces. Since sunlight must be able to penetrate into the cell, at least one of the electrodes must also be transparent to inbound light. In order to prevent energy losses within the cell, the hole and electron collecting electrodes must also not be short-circuited.

### SUMMARY

In some embodiments, a photovoltaic device is disclosed comprising for example an array of columnar structures coated with one or more conformal layers. A thin film microstructure may be provided in which isolated structures extend away from the substrate at predictable angles, for example 0-80° from the substrate normal, and with tunable architectures, for example post-like, helices, chevron-shaped, and these structures, in turn, are conformally coated with organic and/or inorganic materials. The columnar array and conformal coatings act in concert to transform incident electromagnetic energy into electrical energy.

In some embodiments, columnar structures (including but not limited to post-like, helices, chevron-shaped) are deposited by oblique angle physical vapour deposition, wherein vapour flux is directed onto a substrate at an angle (not equal to zero) with respect to the substrate normal. With oblique angle deposition, growing columns extend from the substrate in a direction favouring, but not exactly equivalent to the position of the vapour source. The spacing of the columns may be controlled by varying the oblique deposition angle, and most materials compatible with physical vapour deposition are also compatible with oblique angle physical vapour deposition. The shape and architecture of the columns may be controlled by varying the substrate position through rotation whilst maintaining a known oblique deposition angle.

In some embodiments, the columnar array comprises a wide band gap semiconductor, for example titanium dioxide or an organic wide band gap semiconductor. The wide band gap semiconductor may be optically transparent, allowing most incident light to pass through to the light absorbing material. Due to the large surface area of the semiconductor microstructures, excitons generated in the absorbing material are subsequently provided with a large interfacial area over which they may be dissociated and separated electrons and holes are provided with well defined paths to the collection electrodes.

In some embodiments, the columnar array comprises a transparent conducting oxide (TCO), for example indium tin oxide, zinc oxide, fluorine tin oxide, tin oxide, aluminum zinc oxide, gallium oxide or cadmium oxide. The TCO is optically transparent, allowing most incident light to pass through, yet provides a continuous electrical conduction path. Due to the large surface area of the TCO microstructures, charge carriers are provided with a large area over which they may be injected into the electrode for subsequent transport away from the photovoltaic cell.

In some embodiments, the columnar array comprises a metallic electrical conductor, for example (but not limited to) aluminum. Due to the large surface area of the metal electrode microstructures, charge carriers are provided with a large area over which they may be injected into the electrode for subsequent transport away from the photovoltaic cell.

In some embodiments, the columnar array comprises a series of stacked columnar materials, for example wide band gap semiconductors, transparent conducting oxides, organic semiconductors, metal-organic semiconductors, electrical insulators and metallic conductors. As an example of this aspect, the hole-collecting and electron-collecting electrodes may be deposited in a single columnar structure, separated by an electrical insulator. Using oblique angle deposition, a column made from more than one material may be formed. For example, the column may have a columnar TCO electrode, a columnar electrical insulator, and a second columnar electrode. One of the electrode materials may be chosen such that it will accept electrons, and the other chosen such that it will accept holes. The insulator electrically separates the electrodes, preventing the formation of short-circuits, and it may be chosen such that it forms good columnar structures when deposited at oblique incidence and continues growth along the columns formed by the first electrode material. Due to the large surface area of the dual-electrode microstructures, charge carriers (both electrons and holes) are provided with a large area over which they may be injected into the electrodes for subsequent transport away from the photovoltaic cell.

In some embodiments, a graded-density interfacial layer is provided between the columnar array and one or more substrates. This interfacial layer may or may not be formed by variable angle oblique deposition. The graded-density layer adds structural strength to the columnar array, establishes a consistent column diameter throughout the film, decreases electrical resistance as a result of column narrowing at the base, increases the number density of columns that extend to the full thickness of the film, and can provide the ability to tailor the band gap.

In some embodiments, a photovoltaic device is provided, comprising a first electrode, an electron donor layer in electrical contact with the first electrode, an electron acceptor layer in contact with the electron donor layer across an interface having a shape defined by a columnar structure grown by oblique angle deposition, and a second electrode in electrical contact with the electron acceptor layer. The device may have an optical path for exposing material of at least one of the electron acceptor layer and electron donor layer to solar radiation. The columnar structure may form the electron donor layer, the electron acceptor layer, or one of the first and second electrodes. At least one of the first and second electrodes may be transparent.

In some embodiments, the columnar structure may be deposited onto a substrate by oblique angle physical vapour deposition at an angle from the substrate normal that is greater than at least one of 30°, 60°, 70°, and 75°. The columnar structure may comprise a wide band gap semiconductor such titanium dioxide. The columnar structure may comprise a transparent conducting oxide, for example indium tin oxide, zinc oxide, fluorine tin oxide, tin oxide, aluminum zinc oxide, gallium oxide or cadmium oxide. The columnar structure may comprise an organic semiconductor, for example acenes, fullerenes, thiophenes, anilines, perylenes, imidazoles, quinolines, coronenes, chrysenes, fluorenes, polyfluorenes, polyaromatic hydrocarbons, derivatives, and combinations thereof. The columnar structure may comprise a metal-organic semiconductor, for example a phthalocyanine.

In some embodiments, one of the first and second electrodes underlies the columnar structure, and an interfacial layer may be positioned between the first or second electrode and the columnar array. The interfacial layer may be a graded-density layer, for example a graded-density electrical conductor or semiconductor. The interfacial layer may be formed by variable-angle oblique deposition.

In some embodiments, the columnar structure comprises columns with two or more materials in distinct regions, for example a first electrically conducting material, a second electrically conducting material and an insulator separating the first and second electrically conducting material.

In some embodiments, at least one of the electron donor layer and the electron acceptor layer comprise conducting or semiconducting material, which may or may not be polymeric. The conducting or semiconducting material may comprise one or more of thiophene, poly(thiophene), derivatives of poly(thiophene), pyrroles, anilines, acetylenes, regioregular poly(3-hexylthiophene-2,5-diyl), regiorandom poly(3-hexylthiophene-2,5-diyl), Poly(3,4-ethylenedioxythiophene):poly(styrenesulfonate), C₆₀, derivatives of C₆₀, [6,6]-phenyl-C₆₁-butyric acid methyl ester, C₇₀, [6,6]-phenyl C₇₁-butyric acid methyl ester, fullerenes of all kinds or combinations thereof.

In some embodiments, the photoactive layer comprises a material comprising one or more of CdSe, CdTe, ZnO, and polyelectrolytes comprising PSS sodium (polystyrene sulfonate), PDDA (poly[diallyldimethylammonium chloride]), sodium poly[2-(3-thienyl)ethoxy-4-butylsulfonate], poly[3-(potassium-5-pentanoate)thiophene-2,5-diyl, poly[3-(potassium-6-hexanoate)thiophene-2,5-diyl], derivatives thereof, an electron-donating polymer, and poly-3-hexylthiophene.

In some embodiments, a photovoltaic device is disclosed comprising a first electrode an electron donor layer, an electron acceptor layer, and a second electrode. The electron donor layer is in electrical contact with the first electrode. The electron acceptor layer is in contact with the electron donor layer across an interface having a shape defined by a columnar microstructure, the columnar microstructure comprising columns coated with one or more conformal coatings. The second electrode is in electrical contact with the electron acceptor layer. The columns comprise two or more materials in distinct regions.

In some embodiments, a photovoltaic device is disclosed comprising a first electrode, an electron donor layer, an electron acceptor layer, a second electrode, and a graded density interfacial layer. The electron donor layer is in electrical contact with the first electrode. The electron acceptor layer is in contact with the electron donor layer across an interface having a shape defined by a columnar microstructure. The second electrode is in electrical contact with the electron acceptor layer. The graded density interfacial layer is between the columnar microstructure and one or more substrates, the graded density interfacial layer forming an array of tapered bases for columns of the columnar microstructure.

In some embodiments, a method of making a photovoltaic device is disclosed, comprising: providing a substrate; growing a columnar structure on the substrate using oblique angle deposition; and coating the columnar structure with one or more conformal coatings; in which the columnar structure defines the shape of an interface between an electron acceptor layer in contact with an electron donor layer across the interface, the electron donor layer being in electrical contact with a first electrode and the electron acceptor layer being in electrical contact with a second electrode. The insertion of additional layers such as work function modifiers, hole blocking layers, electron blocking layers, optical interference filters, and the like does not constitute a departure from the essence of the invention, nor does post-processing of the columnar array by any means, including but not limited to annealing, cleaning and chemical functionalization.

### BRIEF DESCRIPTION OF THE DRAWINGS

Embodiments will now be described with reference to the figures, in which like reference characters denote like elements, by way of example, and in which:

FIG. 1 is a cross-sectional view of a photovoltaic device.

FIG. 2 is a cross-sectional view of an example of a photovoltaic device.

FIG. 3 is a cross-sectional view of an insulator-separated dual electrode structure.

FIG. 4 is a scanning electron microscope (SEM) image of a cross-sectional view of a columnar electrically-insulated dual electrode structure.

FIG. 5 is a SEM image of a cross-sectional view of an indium tin oxide columnar array on an indium tin oxide graded density layer.

FIG. 6 is a scanning electron microscope image of a cross-sectional view of an indium tin oxide columnar array conformally coated with electron-donating polythiophene on an indium tin oxide film.

FIG. 7 is a plot of the Time-of-Flight Secondary Ionization Mass Spectroscopy intensity of the elemental count for S, C, Sn, In, and Si versus etch time for the sample in FIG. 6.

FIG. 8A is an SEM image of a columnar array, formed by oblique angle physical vapour deposition of indium tin oxide.

FIG. 8B is a SEM image showing superimposed conformal coatings.

FIG. 9 is a diagram showing an ITO surface with two layers of charged nanorods deposited on top in a sequential fashion.

FIG. 10A shows the ligand exchange scheme used to create amine-functionalized nanorods which become positively charged once immersed in water.

FIG. 10B shows the ligand exchange scheme used to create carboxylate-functionalized nanorods which become negatively charged once immersed in water.

FIG. 11 is a SEM image of a cross-sectional view of a hybrid photovoltaic device incorporating a columnar TiO₂ film and a spin cast poly(3-hexylthiophene) layer interpenetrating the columnar TiO₂ layer.

FIG. 12 is a flowchart illustrating a method of making a photovoltaic device.

### DETAILED DESCRIPTION

Immaterial modifications may be made to the embodiments described here without departing from what is covered by the claims.

In the claims, the word “comprising” is used in its inclusive sense and does not exclude other elements being present. The indefinite article “a” before a claim feature does not exclude more than one of the feature being present. Each one of the individual features described here may be used in one or more embodiments and is not, by virtue only of being described here, to be construed as essential to all embodiments as defined by the claims.

An “ideal” structure for excitonic solar cells may be imagined wherein hole and electron transport layers are interdigitated in a heterogeneous region extending from the hole harvesting electrode to the electron harvesting electrode. The interdigitated arrangement leads to (i) a sufficient thickness of the light-absorbing materials in the elongated vector of the heterogenous region, for example in the direction parallel to the columns, (ii) a large interfacial area with a minimized lateral exciton diffusion pathway for efficient dissociation and charge separation and (iii) it allows charge carrier transport to the appropriate electrodes to proceed in a direct manner, free from scattering sites, charge traps or diffusion/tunneling barriers. This geometry theoretically leads to highly efficient solar cells. In addition, for optimal functioning of the device, the photoactive layers are preferably of a suitable thickness to create sufficient excitons for generation of a reasonable photocurrent, yet be thin enough to minimize recombination events and maximize charge collection. Routine experimentation will yield an optimal thickness.

Thus, a large interfacial area leads to the most efficient excitonic photovoltaic devices, and a columnar array of microstructures formed by oblique angle deposition has a very large interfacial area. Columnar structures may be deposited by oblique angle deposition from a variety of materials including wide band-gap semiconductors, transparent conducting oxides, metals, organic semiconductors, metal-organic semiconductors, and electrical insulators. Wide bandgap semiconductors are semiconductors with bandgaps greater than 1.7 eV. Each of these classes of materials may be deposited using oblique angle deposition for example variable angle oblique deposition, or glancing angle deposition, with exceptionally large surface areas. To do so, a substrate is held at non-zero angle from the substrate normal with respect to an incoming vapour stream of the chosen material. This vapour stream is incident upon the substrate surface, leading to the growth of a thin film. Greater deposition angles lead to enhanced surface shadowing, such that topographic features in the substrate (for example, features formed in the nucleation layer of the growing thin film) cast shadows over nearby areas of the surface. Thus, incoming atoms tend to be incorporated at sites above the largest topographic features. This leads to the formation of a columnar array of structures. These processes are known in the art of oblique angle deposition of materials on surfaces. In particular, glancing angle deposition (GLAD) is described in U.S. Pat. Nos. 5,866,204, 6,206,065 and 6,248,422, and has been used to produce various inorganic thin film structures. FIG. 8A shows an SEM image of one such columnar array, formed by oblique angle physical vapour deposition of the transparent conducting oxide, known as indium tin oxide. This material is a well-known visibly transparent conductor of electricity.

The deposition processes described above, and as described in the above-referenced patents, may be used to form columnar structures, for example post-like, helices, chevron-shaped, etc., on a substrate. The columnar structure may also take other forms that are known in the art of oblique angle physical vapour deposition. In variable angle oblique deposition, the angle may be actively varied. The GLAD technique generally refers to a specific range of deposition angles, approximately 70 degrees or more from the substrate normal. As used below, oblique angle deposition is used as a generic term that encompasses each of these processes. Vapour flux is directed onto the substrate at an angle (not equal to zero) with respect to the substrate normal. With oblique angle deposition, growing columns extend from the substrate in a direction favouring, but not exactly equivalent to the position of the vapour source. The spacing of the columns may be controlled by varying the oblique deposition angle, and most materials compatible with physical vapour deposition are also compatible with oblique angle physical vapour deposition. The shape and architecture of the columns may be controlled by varying the substrate position through rotation whilst maintaining a known oblique deposition angle.

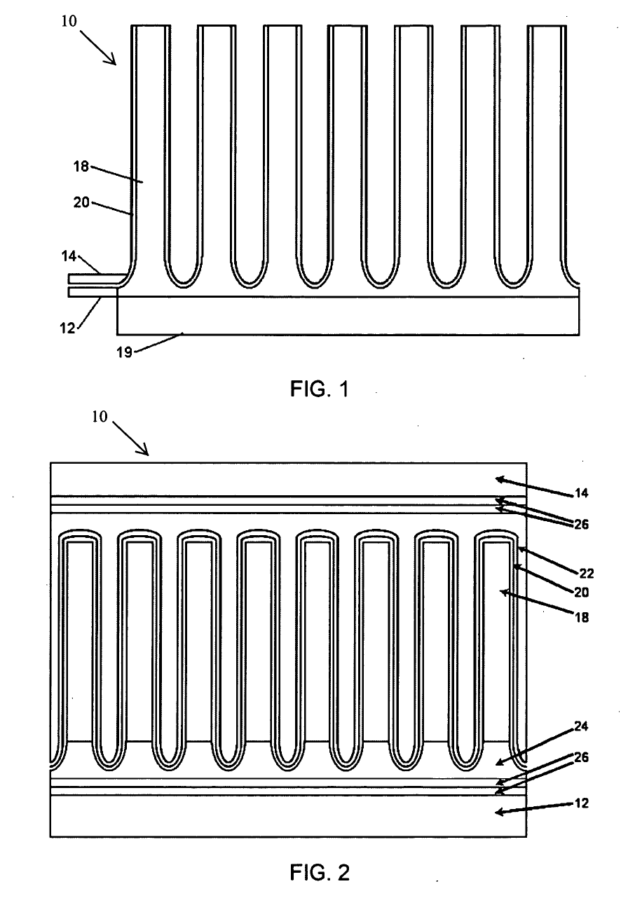

Referring to FIG. 1, a photovoltaic device 10 includes a first electrode (illustrated for example by reference numeral 12), a second electrode (illustrated for example by reference numeral 14), an electron acceptor layer (illustrated for example by coating 20), and an electron donor layer (illustrated for example by columnar structure 18). At least one coating 20 may be present on the columnar structure 18, coating 20 being preferably a conformal coating, made from organic or inorganic materials. The electron acceptor layer is in contact with the electron donor layer across an interface having a shape defined by columnar structure 18 grown by oblique angle deposition. The columnar structure 18 may be formed on a substrate 19 and be a thin film microstructure, in which isolated structures extend away from the substrate 19 at predictable angles, for example between 0-80° from the substrate normal, and that has tunable architectures (post-like, helices, chevron-shaped). The columnar structure 18 may be made up of for example: a wide band gap for example titanium dioxide; a transparent conducting oxide for example indium tin oxide, zinc oxide, fluorine tin oxide, tin oxide, aluminum zinc oxide, gallium oxide and cadmium oxide; an organic semiconductor for example acenes, fullerenes, thiophenes, anilines, perylenes, imidazoles, quinolines, coronenes, chrysenes, fluorenes, polyfluorenes, polyaromatic hydrocarbons and derivatives thereof, a metal-organic semiconductor for example as phthalocyanines; or other materials that are known in the art of oblique angle deposition and that are useful in photovoltaic devices.

The photovoltaic device 10 is designed such that there is an electron donor layer in electrical contact with either electrode 12 or 14, and an electron acceptor layer in electrical contact with the other electrode 14 or 12. The electrodes 12, 14 are shown schematically. Either one or both of the electrodes may span across the top or bottom of the device 10, as shown for example in the embodiment of FIG. 2. The columnar material 18 may also form part of an electrode, or material deposited in between the columnar material 18 may form an electrode. Referring to FIG. 1, as indicated, the interface between the electron donor layer and the electron acceptor layer has a shape, for example a columnar shape, defined by the columnar structure 18. The interface may be defined, for example, by the entirety of the columnar structure (as in FIG. 2) or by at least the cylindrical wall of the columns. The columnar array 18 and conformal coating(s) 20 act in concert to transform incident electromagnetic energy into electrical energy.

In the case where the electrodes span the width of the device for example in the embodiment of FIG. 2, at least one of the electrodes 12 or 14 should be transparent to provide an optical path for light to reach at least one of the electron acceptor and donor layers. In general, an optical light path may be provided for exposing material of at least one of the electron acceptor and electron donor layers to light. The optical path may comprise one of the electron donor layer and the electron acceptor layer being transparent to radiation having a frequency capable of creating excitons in the other of the electron donor layer and electron acceptor layer. The optical light path may be for example from the side of device 10, in which case the columnar material should be transparent. The optical light path refers to the fact that in order for the device to generate current, light must reach at least one of the donor and acceptor layers in order to produce excitons. Thus, the optical path may be defined at least in part by the material or or mediums surrounding and adjacent the absorbing material. The optical light path may provide light to the interface, which by virtue of being adjacent to the donor and acceptor layers, leads to a situation that ensures that excitons are formed close to the interface, thus increasing the efficiency of the device.

The photovoltaic device may take different forms. In one example, the columnar structure 18 is made from an electron donor material, and the coating 20 is made from an electron acceptor material. Alternatively, the columnar structure 18 may be made from the electron acceptor material, and the coating 20 may be made from the electron donor material. When the columnar structure 18 is made from either the electron acceptor or electron donor material, the photovoltaic device may be optimized by shortening the distance between the interface and the electrode to permit more of the charge carriers to reach the electrode 12. It will also be noted that, instead of providing a coating 20 on the columnar structure 18, the electron acceptor or electron donor material may fill the space between the columns. Again, the operation of the device will be improved by providing distances that permit the charge carriers to reach the electrodes. In another example, referring to FIG. 2, the columnar structure 18 may be made from a transparent, conducting material to act as the electrode 12. In this example, two coatings 20 and 22 are present. Coating 20 may be one of electron acceptor and electron donor materials, and coating 22 may be the other of the electron acceptor and electron donor materials. In the example shown, coating 20 is in electrical contact with the columnar structure 18, and the second coating 22 is in electrical contact with the other electrode 14. Each electrode 12, 14 may be effectively made up of one or more materials, for example interfacial layers.

The columnar array 18 may comprise a wide band gap semiconductor, for example titanium dioxide. The wide band gap semiconductor may be optically transparent, allowing most incident light to pass through to the light absorbing material. Due to the large surface area of the semiconductor microstructures, excitons generated in the absorbing material are subsequently provided with a large interfacial area over which they may be dissociated and separated electrons and holes are provided with well defined paths to the collection electrodes 12 and 14.

The columnar array 18 may also comprise a transparent conducting oxide (TCO), for example at least one of indium tin oxide, zinc oxide, fluorine tin oxide, tin oxide, aluminum zinc oxide, gallium oxide, cadmium oxide, or others known in the art of oblique angle deposition and that are useful in photovoltaic devices. The TCO is optically transparent, allowing most incident light to pass through, yet provides a continuous electrical conduction path. The large surface area of the TCO microstructures provides charge carriers with a large area over which they may be injected into the electrode for subsequent transport away from the photovoltaic cell.

The columnar array 18 may also be a metallic electrical conductor, for example aluminum. The large surface area of the metal electrode microstructures provides charge carriers with a large area over which they may be injected into the electrode for subsequent transport away from the photovoltaic cell.

Referring to FIG. 2, other layers may also be included to improve the performance of the photovoltaic device 10. In this example, the columnar array 18 may be a transparent conductor, and may be coated with two conformal layers 20 and 22. Additional layers may also be included aside from layers 20 and 22 as shown. For example, there may be typically a modifying layer, for example LiF, that may be located between a metallic electrode and the active materials. Interfacial layers, for example a graded-density layer 24, or planar films 26 that modify the work function of the electrodes as is known in the art, may also be included. The graded-density layer 24 is discussed below. Referring to FIG. 2, in some embodiments, one of the first and second electrodes 12, 14, underlies the columnar structure 18, and at least one interfacial layer 24 is positioned between the columnar structure 18 and the one of the first and second electrodes that underlie the columnar structure. Electrodes 12 and 14 may be on either side of the device 10 as shown. At least one of the first electrode 12 and second electrode 14 may be transparent, electrode 12 being transparent in this case.

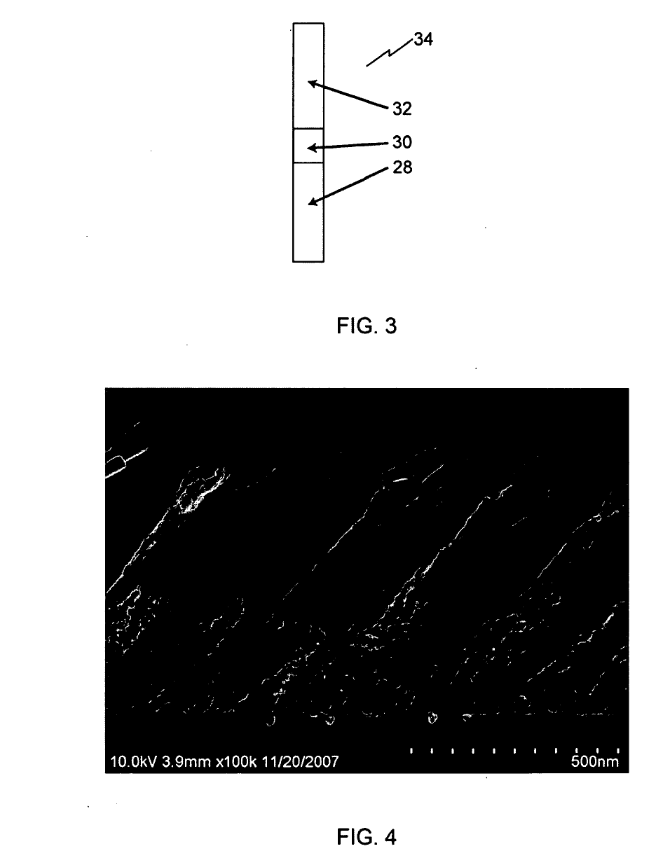

Referring to FIG. 3, this technique may be extended to columnar arrays 18 of more than a single material, for example if the columns comprise two or more materials in distinct regions. In one embodiment, the columnar structure 18 comprises at least one of the first and second electrodes. An electrically-insulated, dual electrode columnar structure may be formed by first depositing a columnar array of a single electrically-conducting material 28 by oblique angle physical vapour deposition. Following this step, a second material 30 is deposited above the first by substituting a second evaporant material and continuing the oblique angle deposition. This material may be chosen such that it is not electrically conducting, and is able to form well-defined columnar structures by oblique angle deposition. Because substrate shadowing conditions have already been established, this second material is preferentially deposited above the columnar structures formed by the first material 28. A third material 32, in this case, a second electrode, is deposited in a similar manner above the pre-formed columnar structure of first material 28 and second material 30. When complete, the full triple-material columnar structure 34 is made up of two electrically-isolated columnar electrodes, one of which is hole-collecting and the other of which is electron-collecting, physically and electrically separated by an interstitial insulator to prevent the formation of short-circuits. The columnar structure 34 may then be conformally coated with the desired coatings to allow the device to operate. A variety of designs may be made. For example, material 28/32 may be an electron donor layer coated with an electron acceptor layer, or an electron acceptor layer coated with an electron donor layer and provided with electrodes as for example in FIG. 1. In another example, conducting material 28 may form an electrode coated with two layers, one an electron donor layer and one an electron acceptor layer as in FIG. 2. Similar arrangements may be made for the second conducting material 30. The coatings may be also separated by insulating material, to provide upper and lower or stacked photovoltaic cells.

The insulator material 30 may be chosen such that it forms good columnar structures when deposited at oblique incidence and continues growth along the columns formed by the first electrode material 28. Examples of suitable materials include wide band gap semiconductors, transparent conducting oxides, organic semiconductors, metal-organic semiconductors, electrical insulators and metallic conductors. Due to the large surface area of the dual-electrode microstructures, charge carriers (both electrons and holes) are provided with a large area over which they may be injected into the electrodes for subsequent transport away from the photovoltaic cell. FIG. 4 shows a scanning electron microscope image of one such structure, wherein the lower electrode is composed of indium tin oxide, the second layer is the electrical insulator silicon dioxide, and the upper electrode is the metallic electrode aluminum.

Potential issues in electrode growth by oblique deposition include the loss of photons by reflection at the abrupt interface between solid (higher refractive index) and columnar (lower refractive index) layers; the presence of shorter columns near the solid/columnar interface and throughout the film; and inconsistent column diameters throughout the film. Extinguished columns which do not grow to the full film thickness do not contribute to charge transport as efficiently as longer columns and thus reduce the overall cell efficiency. Columns with diameters that vary along their length suffer from high electrical resistance (and the associated energy losses) at their narrower points. Tapering structures are also susceptible to shear fracture under even low shear stress due to the long moment arm and low area attachment at the interface. When coating the electrodes with active excitonic materials, these structures are also potentially susceptible to clogging of the structure near top of the film where the columns are widest, and thus the structure potentially incorporates voids once filled. As a result of these issues, an advantage is gained by providing a graded-density interfacial layer 24 between the columnar array 18 and one or more substrates, as shown in FIG. 2. The graded-density layer 24 is most dense near the substrate, and becomes less dense at points more distant from the substrate. This interfacial layer may be formed by variable angle oblique deposition, wherein the deposition angle is modified during growth of the interfacial layer, however other techniques may also be used. When using variable angle oblique deposition to form the graded density layer, a deposition is initiated at a low angle (possibly, but not necessarily equal to zero). Films formed at this low angle tend to be dense and non-columnar. At subsequent points in the deposition run, the deposition angle is increased, and as previously noted, increasingly oblique deposition angles lead to increasingly porous and columnar film microstructures. Thus a graded-density structure is formed by a transition from less to more oblique deposition, and the transition process may be continuous or step-wise. The graded-density layer 24 adds structural strength to the columnar array, establishes a consistent column diameter throughout the film, decreases electrical resistance as a result of column narrowing at the base, and increases the number density of columns that extend to the full thickness of the film. The graded-density layer 24 may be an electrical conductor or semiconductor. The graded density interfacial layer may be between the columnar microstructure and one or more substrates. In some embodiments, the graded density interfacial layer forms an array of tapered bases for columns of the columnar microstructure, as shown for example in FIG. 2.

Referring to FIG. 3, in some embodiments, the columnar microstructure 18 may comprise columns 34 coated with one or more conformal coatings 20 (shown in FIG. 1 for example), wherein the columns 34 comprise two or more materials in distinct regions. The two or more materials of the columns 34 may be stacked together (as shown) to form the columns.

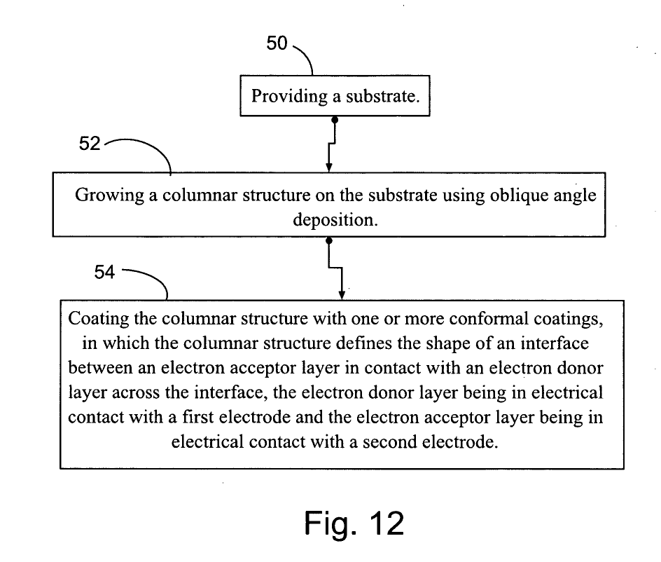

Referring to FIG. 12, a method of making a photovoltaic device 10 is illustrated. Referring to FIG. 1, in a stage 50, a substrate 19 is provided. In a stage 52, a columnar structure, for example structure 18, is grown on the substrate 19 using oblique angle deposition. Referring to FIG. 3, stage 52 may further comprise depositing a first material (for example material 28) on the substrate (not shown) in a columnar array (shown for example in FIG. 1), depositing an insulator 30 on the first material to extend the columnar array, and depositing a second material (for example material 32) on the insulator to extend the columnar array. Referring to FIG. 1, in a stage 54, the columnar structure 18 is coated with one or more conformal coatings 20.

### Conformal Coatings

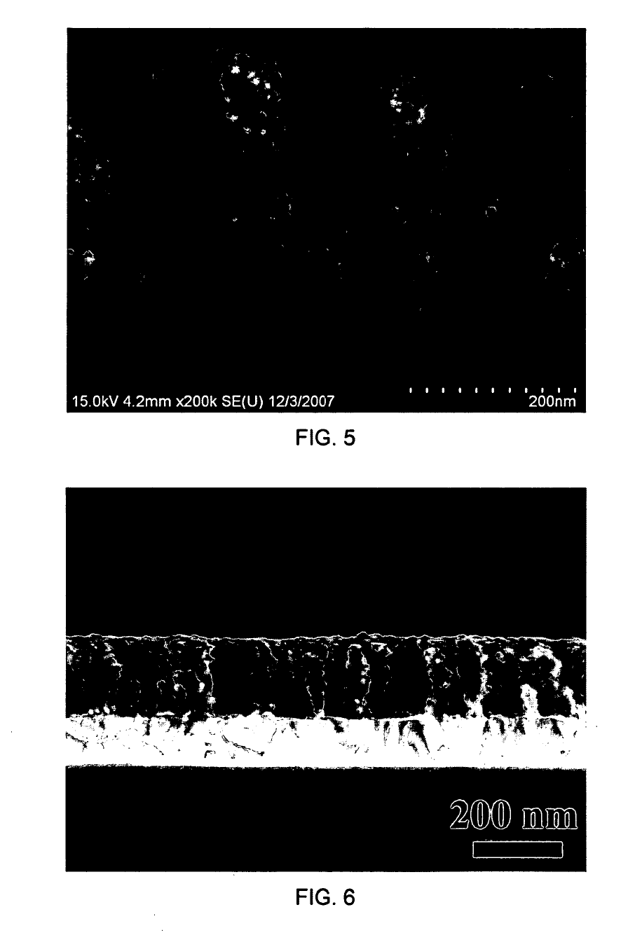

For conformal coating of the columnar structures, the substrate (as in FIG. 5 for example) may be electrochemically coated in one embodiment with a film of conducting or semi-conducting polymers, for example poly(thiophene), derivatives of poly(thiophene), regioregular poly(3-hexylthiophene-2,5-diyl), regiorandom poly(3-hexylthiophene-2,5-diyl), poly(3,4-ethylenedioxythiophene):poly(styrenesulfonate), C₆₀, derivatives of C₆₀, and [6,6]-phenyl-C₆₁-butyric acid methyl ester, C₇₀, [6,6]-phenyl C₇₁-butyric acid methyl ester, or fullerenes of all kinds.

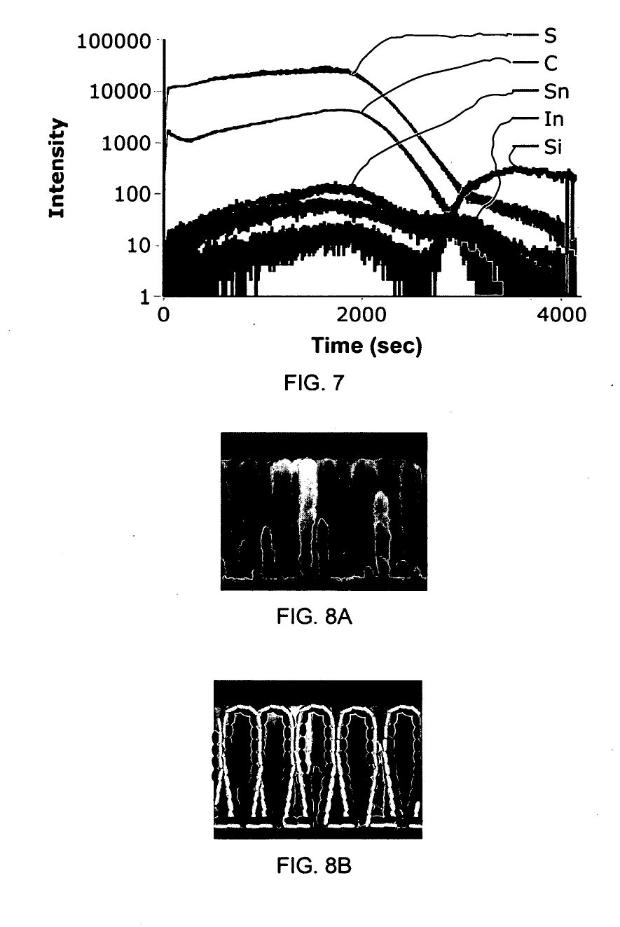

To apply the film in one embodiment, the substrate may be electrically contacted and immersed with a counter electrode in an electrolytic bath containing a compound which may be one or more of thiophene, 3-methylthiophene, 3-ethylthiophene, 3-propylthiophene, 3-bromothiophene, 3-phenylthiophene, 3,4-dimethylthiophene, 3,4-diethylthiophene, 3,4-ethylenedioxythiophene, 2,2′-bithiophene, and 2,2′-dithienylethylene, and a supporting electrolyte which may be one or more of tetrabutyl ammonium trifluoromethanesulfonate, tetrabutyl ammonium tetrafluoroborate, tetrabutyl ammonium hexafluorophosphate, and boron trifluoride diethyl etherate and applying a positive voltage on the substrate as an electrode to induce polymerization of the thiophene compound and form a coating of the resulting polymer on the surface of the substrate. Note that, for most preparations of conformal layers with the supporting electrolytes listed above except for boron trifluoride diethyl etherate, a solvent medium may be required. This may be, for example, dichloromethane, chloroform, acetonitrile, etc. Referring to FIG. 6, a indium tin oxide columnar array is shown that has been conformally coated with electron-donating polythiophene on an indium tin oxide film. FIG. 7 is a plot of the Time-of-Flight Secondary Ionization Mass Spectroscopy intensity of the elemental count for S, C, Sn, In, and Si versus etch time for the sample shown in FIG. 6.

In another embodiment, for conformal coating of the columnar structures, the substrate (as in FIG. 5, for example) may be coated by for example vapour phase or solution phase functionalization with a film of conducting or semi-conducting molecules or polymers to enhance wetting, electrical contact, adhesion, nucleation during electrochemical deposition of conformal films, energy level matching (through physical and/or covalent means). For example, a transition metal oxidized or catalyzed polymerization of thiophene-containing monomers using surface immobilized initiators may be conducted. First, a layer of an thiophene- or aryl halide-containing compound may be formed on the substrate from a period of immersion (0.25-7 days) in, or in a solution of, one or more of (i) thiophene-containing compound(s) of the general formula (C₄H₃S)—(CH₂)ₙ—SiX₃ (where either 2- or 3-substitution of thiophene is possible and n≧0; X═Cl, OMe, OEt), (ii) thiophene-containing compound(s) of the general formula (C₄H₃S)—Y—(CH₂)ₙ—SiX₃ (where either 2- or 3-substitution of thiophene is possible and n≧0; Y═O, S, COO, CONH; X═Cl, OMe, OEt; as in for example 2-(3-trimethoxysilylpropylthio)thiophene), (iii) other thiophene-containing compound(s) for example 2-bromo-3-(trimethoxysilyl)thiophene, 2-(trimethoxysilyl)-3-bromothiophene, triethoxy-2-thienylsilane, triethoxy-3-thienylsilane, 2-bromo-3-(triethoxysilyl)thiophene, 2-(triethoxysilyl)-3-bromothiophene, (iv) aryl halide-containing compound(s) of the general formula (BrC₆H₄)—(CH₂)ₙ—SiX₃ (where either 2-, 3-, 4-substitution of aromatic ring is possible and n≧0; X═Cl, OMe, OEt as in for example 4-bromophenyltrimethoxysilane, 3-bromophenyltrimethoxysilane, 2-bromophenyltrimethoxysilane, 4-bromophenyltriethoxysilane, 3-bromophenyltriethoxysilane and 2-bromophenyltriethoxysilane) at temperatures in the range of 25-100° C. Second, a transition metal oxidant or catalyst may be introduced via placing the substrate into a vessel with a solution (0.05-2 wt % solvent) of one or more of Ni(PPh₃)₄ , Ni(bipy)Cl₂, Pd(acac)₂, Ni(acac)₂, Co(acac)₂, Fe(acac)₃, Ni(dppp)Cl₂, Ni(cod)₂, FeCl₃, PdCl₂ and allowed to react. Extensive washing with dry solvent may or may not be executed followed by the introduction of a solution (0.05-10 wt % solvent) of one or more of thiophene, 2,5-dichlorothiophene, 2,5-dibromothiophene, 2,5-diiodothiophene, 2-bromo-5-iodothiophene, 2-bromo-5-iodothiophene, 2-bromo-5-chloromagnesiothiophene, 2-bromo-5-iodomagnesiothiophene, 3-hexylthiophene, 2,5-dichloro-3-hexylthiophene, 2,5-dibromo-3-hexylthiophene, 2,5-diiodo-3-hexylthiophene, 2-bromo-3-hexyl-5-iodothiophene, 2-bromo-5-chloromagnesio-3-hexylthiophene, and 2-bromo-5-iodomagnesio-3-hexylthiophene and allowed to react. Finally, the substrate is extensively rinsed with 5 M HCl, water, organic solvents and dried. In a further example, columnar ITO may be functionalized by vapor phase functionalization and applied towards the electrochemical deposition of semi-conducting polymers.

In another embodiment, for conformal coating of the columnar structures, the substrate (as in FIG. 5 for example) may be coated with a film of conducting or semi-conducting polymers through a combination of electrochemical deposition and transition metal catalyzed polymerization from its surface. First, a polymeric layer of an aryl halide containing material which may be one or more of poly(3-bromothiophene-2,5-diyl), poly(3-iodothiophene-2,5-diyl), poly(3,4-dibromothiophene-2,5-diyl), and poly(3,4-diiodothiophene-2,5-diyl) is deposited electrochemically as above. Second, a film of conducting or semi-conducting polymer is grown through a transition metal catalyzed polymerization using surface immobilized initiators as above.

In another embodiment, columnar structures may be conformally coated with an organic or polymeric material by spin casting, drop casting, or melt casting, producing an interpenetrating hybrid material. A TiO₂/poly(3-hexylthiophene) device fabricated in this manner is presented in FIG. 11.

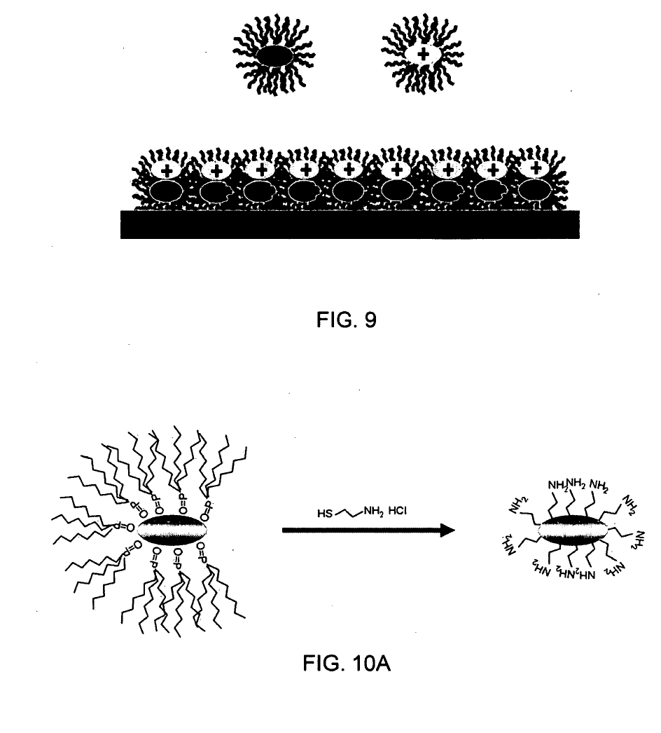

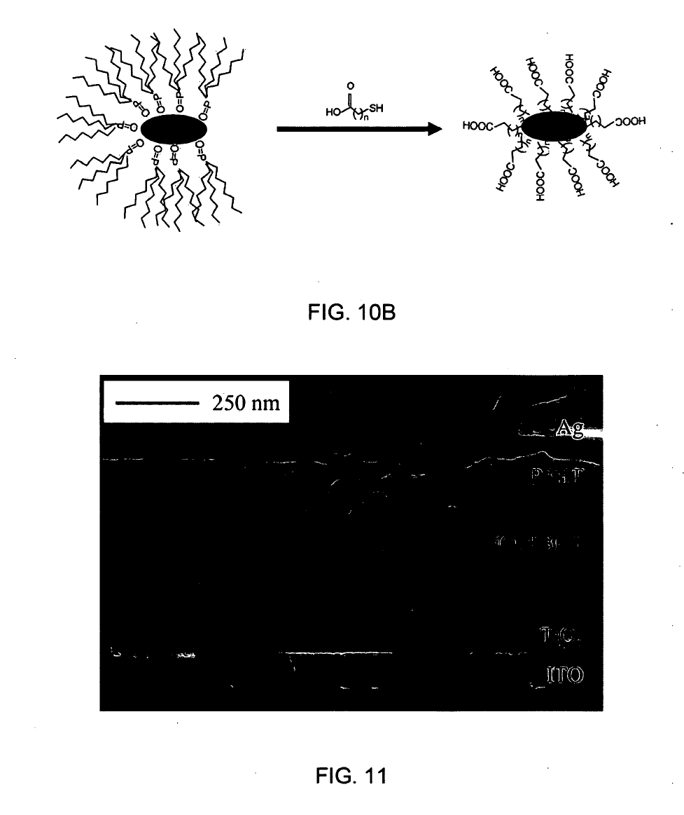

In addition to conformal coatings made of polythiophene, another aspect will involve conformal coatings of the columnar structures using either covalent or electrostatic layer by layer deposition of the photoactive layer. The method may be used to create either all-inorganic or inorganic/organic photovoltaic heterojunctions on top of the columnar structures, as shown in FIG. 8B. The process involves for example tailoring the surface charge, as shown in FIG. 9, by growing nanorod layers of differing surface charge on the columns, or chemically activating the semiconductor nanostructures of varying aspect ratio, as shown in FIGS. 10A and 10B. In FIG. 9, only a single layer for each nanorod type (+ or −) is shown for simplicity. FIG. 10A shows a quantum dot being functionalized to adsorb a positively charged coating. Small aspect ratio structures are commonly referred to as quantum dots and larger aspect ratio structures as nanorods. FIG. 10B shows a cadmium selenide nanoparticle being functionalized to adsorb a negatively charged coating. The semiconductor nanostructure material are generally the type II-VI semiconductors Cadmium Selenide (CdSe), Cadmium Telluride (CdTe) and/or Zinc Oxide (ZnO).

In one embodiment, electrostatic self-assembly is used. The surface charge may be tailored using ligand exchange chemistry with functional groups that have either permanent or pH-sensitive charges. The negative charge is imparted onto the above mentioned nanostructures using the carboxylate ligand in the ligand exchange chemistry process. The positive charge is imparted on the above mentioned nanostructures using the amine (which will become ammonium) ligand in the ligand exchange chemistry process.

Using a simple dip-coating procedure, the GLAD substrate may be sequentially dipped into positive and negative aqueous solutions of the II-VI semiconductors thereby forming a nano-scale controlled thin film. The indium tin oxide columnar electrodes (made using GLAD) are derivitized with amine functionalities using a silanization bath reaction with either aminopropyltriethoxysilane or aminopropyltrimethoxysilane in toluene at about 60° C. for anywhere from 1-120 minutes thus imparting a positive charge onto the GLAD electrode. This electrode is dipped into an aqueous solution of negatively charged nanostructures thus forming the first layer of nanostructures onto the GLAD surface. The next layer is either another of the above mentioned nanostructures or a polyelectrolyte carrying the opposite charge of the previous layer. (for example PSS sodium (polystyrene sulfonate) and/or PDDA (poly[diallyldimethylammonium chloride] and/or sodium poly[2-(3-thienyl)ethoxy-4-butylsulfonate] and/or poly[3-(potassium-5-pentanoate)thiophene-2,5-diyl, and/or poly[3-(potassium-6-hexanoate)thiophene-2,5-diyl], derivatives thereof) This process is repeated until the desired film thickness is achieved. The resulting film with be either all-inorganic CdSe/CdTe bilayer or inorganic/organic CdSe/polyelectrolyte or CdTe/polyelectrolyte with a conducting or semiconducting polymer either spin-coated or dip-coated on top.

In addition to electrostatic self-assembly, covalent interactions can be used to form the sequential layers of nanostructures. If the amine and carboxylate groups are activated using EDC (1-Ethyl-3-(3-dimethylaminopropyl)-carbodiimide) or any other reagent that forms activated esters it is possible to covalently create amide bonds between either the above mentioned nanostructures or the nanostructures and the polyelectrolyte. In this manner sequential dipping will also allow layers to self-assemble onto the GLAD electrode in a sequential fashion, however this time all layers and nanostructures within these layers are covalently attached.

Light in this document refers to radiation with a frequency capable of creating excitons in at least one of the electron donor and electron acceptor layers. Non-limiting examples of suitable radiation include solar radiation, visible frequencies, ultraviolet frequencies, infrared frequencies. Transparent in this document refers to a property of a material that allows radiation to pass through the material, the passed radiation having at least one frequency capable of creating excitons in the donor or acceptor layer. Conformal in this document refers to material that covers, and has a shape defined by, at least an operative portion of the columnar structure. Non-limiting examples include a film coating the columns, and a film coating the cylindrical walls of the columns.

1. A photovoltaic device, comprising:
a first electrode;
an electron donor layer in electrical contact with the first electrode;
an electron acceptor layer in contact with the electron donor layer across an interface having a shape defined by a columnar structure grown by oblique angle deposition; and
a second electrode in electrical contact with the electron acceptor layer.

2. The photovoltaic device of claim 1, further comprising an optical path for exposing material of at least one of the electron acceptor layer and electron donor layer to solar radiation.

3. The photovoltaic device of claim 2 in which the optical path comprises one of the electron donor layer and the electron acceptor layer being transparent to radiation having a frequency capable of creating excitons in the other of the electron donor layer and electron acceptor layer.

4. The photovoltaic device of claim 1 in which the columnar structure forms at least one of the electron donor layer and the electron acceptor layer.

5. The photovoltaic device of claim 1 in which the columnar structure comprises at least one of the first and second electrodes.

6. The photovoltaic device of claim 1 in which at least one of the first electrode and the second electrode are transparent.

7. The photovoltaic device of claim 1 in which the columnar structure is deposited onto a substrate at an angle from the substrate normal that is greater than at least one of 30°, 60°, 70°, and 75°.

8. The photovoltaic device of claim 1 in which the columnar structure comprises a wide band gap semiconductor.

9. The photovoltaic device of claim 8 in which the wide band gap semiconductor comprises titanium dioxide.

10. The photovoltaic device of claim 1 in which the columnar structure comprises a transparent conducting oxide.

11. The photovoltaic device of claim 10 in which the transparent conducting oxide comprises one or more of indium tin oxide, zinc oxide, fluorine tin oxide, tin oxide, aluminum zinc oxide, gallium oxide and cadmium oxide.

12. The photovoltaic device of claim 1 in which the columnar structure comprises an organic semiconductor.

13. The photovoltaic device of claim 12 in which the organic semiconductor comprises one or more of acenes, fullerenes, thiophenes, anilines, perylenes, imidazoles and quinolines, coronenes, chrysenes, fluorenes, polyfluorenes, polyaromatic hydrocarbons, derivatives and combinations thereof.

14. The photovoltaic device of claim 1 in which the columnar structure comprises a metal-organic semiconductor.

15. The photovoltaic device of claim 14 in which the metal-organic semiconductor comprises phthalocyanines.

16. The photovoltaic device of claim 1 in which one of the first and second electrodes underlies the columnar structure, and further comprising an interfacial layer positioned between the columnar structure and the one of the first and second electrodes that underlie the columnar structure.

17. The photovoltaic device of claim 16 in which the interfacial layer is a graded-density layer.

18. The photovoltaic device described in claim 17 in which the interfacial layer is a graded-density electrical conductor or semiconductor.

19. The photovoltaic device of claim 16 in which the interfacial layer is formed by variable-angle oblique deposition.

20. The photovoltaic device of claim 1 in which the columnar structure comprises columns with two or more materials in distinct regions.

21. The photovoltaic device of claim 20 in which the columnar structure comprises a series of stacked columnar materials.

22. The photovoltaic device of claim 21 in which the stacked columnar materials comprise the first electrode, the second electrode, and an insulator separating the first electrode and the second electrode.

23. The photovoltaic device of claim 1 in which at least one of the electron donor layer and the electron acceptor layer comprise conducting or semiconducting material.

24. The photovoltaic device of claim 23 in which the conducting or semiconducting material is at least one of molecular and polymeric, and comprises one or more of poly(thiophene), derivatives of poly(thiophene), regioregular poly(3-hexylthiophene-2,5-diyl), regiorandom poly(3-hexylthiophene-2,5-diyl), C60, derivatives of C60, [6,6]-phenyl-C61-butyric acid methyl ester, C70, [6,6]-phenyl C71-butyric acid methyl ester, or fullerenes of all kinds.

25. The photovoltaic device of claim 1 in which at least one of the electron donor layer and the electron acceptor layer comprise materials comprising one or more of CdSe, CdTe, ZnO, and polyelectrolytes, PSS sodium (polystyrene sulfonate), PDDA (poly[diallyldimethylammonium chloride]), sodium poly[2-(3-thienyl)ethoxy-4-butylsulfonate], poly[3-(potassium-5-pentanoate)thiophene-2,5-diyl, poly[3-(potassium-6-hexanoate)thiophene-2,5-diyl], derivatives thereof, an electron-donating polymer, and poly-3-hexylthiophene.

26. A photovoltaic device comprising:
a first electrode;
an electron donor layer in electrical contact with the first electrode;
an electron acceptor layer in contact with the electron donor layer across an interface having a shape defined by a columnar microstructure, the columnar microstructure comprising columns coated with one or more conformal coatings; and
a second electrode in electrical contact with the electron acceptor layer;
wherein the columns comprise two or more materials in distinct regions.

27. The photovoltaic device described in claim 26, wherein the columnar microstructure comprises two electrically conducting materials separated by an electrical insulator.

28. The photovoltaic device of claim 25 in which the two or more materials of the columns are stacked together to form the columns.

29. A photovoltaic device comprising:
a first electrode;
an electron donor layer in electrical contact with the first electrode;
an electron acceptor layer in contact with the electron donor layer across an interface having a shape defined by a columnar microstructure;
a second electrode in electrical contact with the electron acceptor layer; and
a graded density interfacial layer between the columnar microstructure and one or more substrates, the graded density interfacial layer forming an array of tapered bases for columns of the columnar microstructure.

30. A method of making a photovoltaic device comprising:
providing a substrate;
growing a columnar structure on the substrate using oblique angle deposition; and
coating the columnar structure with one or more conformal coatings;
in which the columnar structure defines the shape of an interface between an electron acceptor layer in contact with an electron donor layer across the interface, the electron donor layer being in electrical contact with a first electrode and the electron acceptor layer being in electrical contact with a second electrode.

31. The method of claim 30 in which growing the columnar structure further comprises:
depositing a first material on the substrate in a columnar array;
depositing an insulator on the first material to extend the columnar array; and
depositing a second material on the insulator to extend the columnar array.
